(19) United States
(12) Patent Application Publication
(10) Pub. No.: US 2008/0315396 A1
(43) Pub. Date: Dec. 25, 2008

(54) Mold compound circuit structure for enhanced electrical and thermal performance

(75) Inventors: Mark A. Kuhlman, Laguna Niguel, CA (US); Anil Agarwal, Ladera Ranch, CA (US)

Correspondence Address: FARJAMI & FARJAMI LLP, 26522 LA ALAMEDA AVENUE, SUITE 360, MISSION VIEJO, CA, 92691, US

(73) Assignee: SKYWORKS SOLUTIONS, INC., Woburn, MA (US)

(21) Appl. No.: 12/152,189

(22) Filed: May 12, 2008

Related U.S. Application Data
(60) Provisional application No. 60/936,821, filed on Jun. 22, 2007.

(51) Int. Cl. H01L 23/48; H01L 21/56

(52) U.S. Cl. 257/692; 438/127; 257/E23.01; 257/E21.502

(57) ABSTRACT

According to an exemplary embodiment, an overmolded semiconductor package includes at least one semiconductor die situated over a package substrate. The overmolded semiconductor package further includes a mold compound overlying the at least one semiconductor die and the package substrate and having a top surface. The overmolded semiconductor package further includes a first patterned conductive layer situated on the top surface of the mold compound. The overmolded semiconductor package can further include at least one conductive interconnect situated in the mold compound, where the at least one conductive interconnect is electrically connected to the first patterned conductive layer. The first patterned conductive layer can include at least one passive component.

The present application claims the benefit of and priority to a pending provisional patent application entitled “Mold Compound Circuit Structure for Enhanced Electrical and Thermal Performance,” Ser. No. 60/936,821 filed on Jun. 22, 2007. The disclosure in that pending provisional application is hereby incorporated fully by reference into the present application.

### BACKGROUND OF THE INVENTION

1. Field of the Invention

The present invention generally relates to the field of semiconductors. More particularly, the invention relates to the fabrication of overmolded semiconductor packages.

2. Background Art

For mobile electronic devices, such as cell phones, as well as stationary electronic devices, increased functionality and device miniaturization have increased the complexity of semiconductor packages in the electronic devices and the circuit boards they (i.e. the semiconductor packages) are mounted on. As a further result of increased functionality and device miniaturization, available circuit board space in mobile electronic devices, such as cell phones, is generally reduced, thereby causing the circuitry in these devices to be more closely packed. As a result, the thermal performance of an active component, such as a power amplifier, which is typically encapsulated in a semiconductor package and mounted on a circuit board in a mobile electronic device, such as a cell phone, can be undesirably affected.

In an effort to save circuit board space in electronic devices, such as cell phones, a conventional approach has been to “stack” semiconductor packages, such as Ball Grid Array (BGA) packages, on a circuit board. In this conventional approach, a first (lower) BGA package has perimeter surface mounts pads on the top surface of the package substrate that are aligned with solder balls on the bottom surface of a second (upper) BGA package. However, this conventional stacking approach requires exposed perimeter surface mount pads on the package substrate, which undesirably increases the package footprint. Also, in high frequency applications, routing a signal to the perimeter of a package up through a BGA ball can create unwanted inductance and signal loss.

To improve thermal performance, a conventional approach, which can be applied to either lead frame packages or BGA packages, is to embed a thermal heat spreader into the semiconductor package. However, adding an embedded heat spreader undesirably increases the manufacturing cost of the semiconductor package. Also, embedded heat spreaders can create thermal expansion mismatch with a heat-generating silicon or gallium arsenide semiconductor die. As such, embedded heat spreaders must be carefully designed and use materials which are both thermally conductive and match the thermal expansion properties of the semiconductor die.

### SUMMARY OF THE INVENTION

Mold compound circuit structure for enhanced electrical and thermal performance; substantially as shown in and/or described in connection with at least one of the figures, as set forth more completely in the claims.

### BRIEF DESCRIPTION OF THE DRAWINGS

FIG. 1 shows a cross-sectional view of an exemplary overmolded semiconductor package including an exemplary mold compound circuit structure, in accordance with one embodiment of the present invention.

FIG. 2 shows a top view of an exemplary overmolded semiconductor package including an exemplary patterned conductive layer situated over a mold compound, in accordance with one embodiment of the present invention.

FIG. 3 shows a side view of an exemplary structure including two stacked exemplary semiconductor packages situated over a circuit board, in accordance with one embodiment of the present invention.

FIG. 4 shows a cross-sectional view of exemplary overmolded semiconductor package including an exemplary mold compound circuit structure including a number of thermal vias situated in a mold compound, in accordance with one embodiment of the present invention.

FIG. 5A shows a top view of an exemplary overmolded semiconductor package including two exemplary patterned conductive layers overlying a mold compound, in accordance with one embodiment of the present invention.

FIG. 5B shows a side view of the exemplary overmolded semiconductor package of FIG. 5A.

FIG. 6A shows a top view of an exemplary overmolded semiconductor package including an exemplary patterned conductive layer overlying a mold compound and a flexible connector overlying the exemplary patterned conductive layer, in accordance with one embodiment of the present invention.

FIG. 6B shows a side view of the exemplary overmolded semiconductor package of FIG. 6A.

FIG. 7A shows a top view of an exemplary overmolded semiconductor package including an exemplary patterned conductive layer overlying a mold compound and a number of surface mount components overlying the exemplary patterned conductive layer, in accordance with one embodiment of the present invention.

FIG. 7B shows a side view of the exemplary overmolded semiconductor package of FIG. 7A.

### DETAILED DESCRIPTION OF THE INVENTION

The present invention is directed to mold compound circuit structure for enhanced electrical and thermal performance. The following description contains specific information pertaining to the implementation of the present invention. One skilled in the art will recognize that the present invention may be implemented in a manner different from that specifically discussed in the present application. Moreover, some of the specific details of the invention are not discussed in order to not obscure the invention. The specific details not described in the present application are within the knowledge of a person of ordinary skill in the art.

The drawings in the present application and their accompanying detailed description are directed to merely exemplary embodiments of the invention. To maintain brevity, other embodiments of the invention which use the principles of the present invention are not specifically described in the present application and are not specifically illustrated by the present drawings.

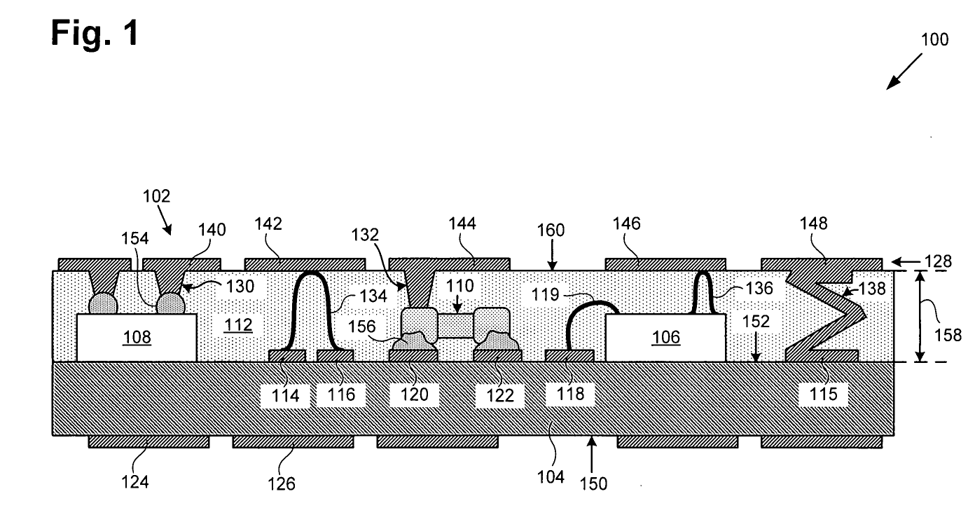

FIG. 1 shows a cross-sectional view of overmolded semiconductor package 100 including an exemplary mold compound circuit structure in accordance with one embodiment of the present invention. Certain details and features have been left out of FIG. 1 that are apparent to a person of ordinary skill in the art. Overmolded semiconductor package 100 includes mold compound circuit structure 102, package substrate 104, semiconductor die 106 (hereinafter referred to simply as “die 106”), semiconductor die package 108 (hereinafter referred to simply as “die package 108”), surface mount component 110, mold compound 112, bond pads 114, 115, 116, and 118, metal wire 119, solder pads 120 and 122, and input/output (I/O) pads 124 and 126. Mold compound circuit structure 102 includes patterned conductive layer 128, conductive vias 130 and 132, metal wires 134 and 136, and metal structure 138. Patterned conductive layer 128 includes conductive pads 140, 142, 144, 146, and 148 (hereinafter “conductive pads 140 through 148”). Patterned conductive layer 128 can also include one or more inductors and/or capacitors, which are not shown in FIG. 1. Overmolded semiconductor package can be, for example, a land grid array (LGA) package. It is noted that only conductive pads 140 through 148 and I/O pads 124 and 126 are specifically discussed herein to preserve brevity.

As shown in FIG. 1, I/O pads 124 and 126 are situated on bottom surface 150 of package substrate 104 and can be, for example, LGA I/O pads. I/O pads 124 and 126 can comprise copper, aluminum, or other suitable metal and can be formed on bottom surface 150 of package substrate 104 in a manner known in the art. Package substrate 104 can be, for example, a laminate or ceramic substrate or a substrate comprising a mixture of laminate and ceramic material and can include conductive vias (not shown in FIG. 1). In one embodiment, package substrate 104 can be a multilayer laminate substrate and can include conductive vias and one or more metal layers. Also shown in FIG. 1, die 106, die package 108, bond pads 114, 115, 116, and 118, and solder pads 120 and 122 are situated on top surface 152 of package substrate 104. Die 106 can be attached to package substrate 104 by, for example, a suitable die attach material and can be coupled to bond pad 118 by metal wire 119. Die package 108 can be, for example, a flip chip package or a chip scale package (CSP) and can be attached to package substrate 102 by epoxy or other suitable material. Die package 108 can include solder balls, such as solder ball 154, for I/O interconnections. In another embodiment, die pads can be utilized for I/O interconnections to die package 108.

Bond pads 114, 115, 116, and 118 can comprise copper, aluminum, gold, or other suitable metal or metal stack and can be formed on top surface 152 of package substrate 104 in a manner known in the art. Further shown in FIG. 1, surface mount component 110 is electrically connected to solder pads 120 and 122 by solder 156 and can be a passive component, such as capacitor, resistor, or inductor. Also shown in FIG. 1, metal wire 134 is connected between bond pads 114 and 116 and metal wire 136 is connected to bond pads (not shown in FIG. 1) on die 106. Also shown in FIG. 1, metal structure 138 is attached to bond pad 115 and can comprise copper, gold, or other suitable metal. Metal structure 138 can be a metal coil or spring for providing an electrical connection between bond pad 115 and conductive pad 148 in patterned conductive layer 128. In one embodiment, metal structure 138 can be an inductor.

Further shown in FIG. 1, mold compound 112 is situated over top surface 152 of package substrate 104 and encapsulates die 106, die package 108, surface mount component 110, bond pads 114, 115, 116, and 118, solder pads 120 and 122, metal wires 119, 134 and 136 and metal structure 138. Mold compound 112 can comprise an epoxy or other suitable molding or encapsulation material and has thickness 158, which can be, for example, between 0.15 millimeter (mm) and 1.0 mm. In the present embodiment, mold compound 112 can extend over the entire top surface of package substrate 104. In one embodiment, mold compound 112 can extend over a portion of top surface 152 of package substrate 104. Also shown in FIG. 1, conductive vias 130 and 132 are situated in mold compound 112 and can comprise copper, gold, or other suitable metal or metal stack, a conductive epoxy, or other suitable conductive material. Conductive via 130 is electrically connected to solder ball 154 and conductive via 132 is electrically connected to a terminal of surface mount compound 110. Conductive vias 130 and 132 can be formed by forming holes in mold compound 112 by utilizing laser ablation, a mechanical drilling process, or other suitable process and filling the holes with a conductive material, such as metal or conductive epoxy.

Further shown in FIG. 1, conductive pads 140 through 148 of patterned conductive layer 128 are situated on top surface 160 of mold compound 112 and can comprise copper, copper and nickel, a conductive epoxy, or other suitable conductive material. Conductive pad 140 is electrically connected to die package 108 conductive via 130, conductive pad 142 is electrically connected to bond pads 114 and 116 by metal wire 134, and conductive pad 144 is electrically connected to surface mount component 110 by conductive via 132. Also, conductive pad 146 is electrically connected to die 106 by metal wire 136 and conductive pad 148 is electrically connected to bond pad 115 by metal structure 138. Patterned conductive layer 128 can be formed by depositing a layer of conductive material, such as copper, on top surface 160 of mold compound 112 by utilizing an electrochemical deposition process or other suitable deposition processes and appropriately patterning the conductive layer to form conductive pads 140 through 148. Patterned conductive layer 128 may also be formed on top surface 160 of mold compound 112 by utilizing, for example, a screen printing process or photo etching process.

Prior to formation of patterned conductive layer 128, an appropriate amount of molding material can be removed by utilizing plasma, laser, or mechanical ablation to expose metal wires 134 and 136 on top surface 160 of mold compound 112. A suitable cleaning process can then be performed to clean the exposed portions of metal wires 134 and 136 so as to ensure a high quality electrical connection between metal wires 134 and 136 and respective conductive pads 142 and 146 of patterned conductive layer 128 when patterned conductive layer 128 is formed.

In the embodiment in FIG. 1, the invention's mold compound circuit structure 102 includes patterned conductive layer 128, which is formed on top surface 160 of mold compound 112 and which can include passive components (not shown in FIG. 1), such as capacitors and inductors, and conductive interconnects including conductive vias 130 and 132, metal wires 134 and 136, and metal structure 138, which are formed in mold compound. The conductive interconnects provide electrical connections between patterned conductive layer 128 and active devices, such as die 106 and die package 108, passive devices, such as surface mount component 110, and bond pads, such as bonds pads 114, 115, and 116, which are situated on top surface 152 of package substrate 104.

Thus, the invention provides a mold compound circuit structure that utilizes the top surface of a mold compound in an overmolded semiconductor package for patterning metal pads and passive components, which can be interconnected to active and passive devices on the package substrate by conductive interconnects formed in the mold compound. In one embodiment, the invention's mold compound circuit structure may not be connected to active or passive components or bond pads on the package substrate, but may be electrically connected to external devices. In one embodiment, the invention's mold compound circuit structure can include multiple patterned conductive layers, such as patterned conductive layer 128, formed over top surface 160 of mold compound 112.

Thus, by forming a mold compound circuit structure on the top surface of mold compound in an overmolded semiconductor package, the invention advantageously provides a patterned conductive layer, which can include conductive pads and passive components, on an area of the overmolded semiconductor package that is conventionally unused for such circuit elements.

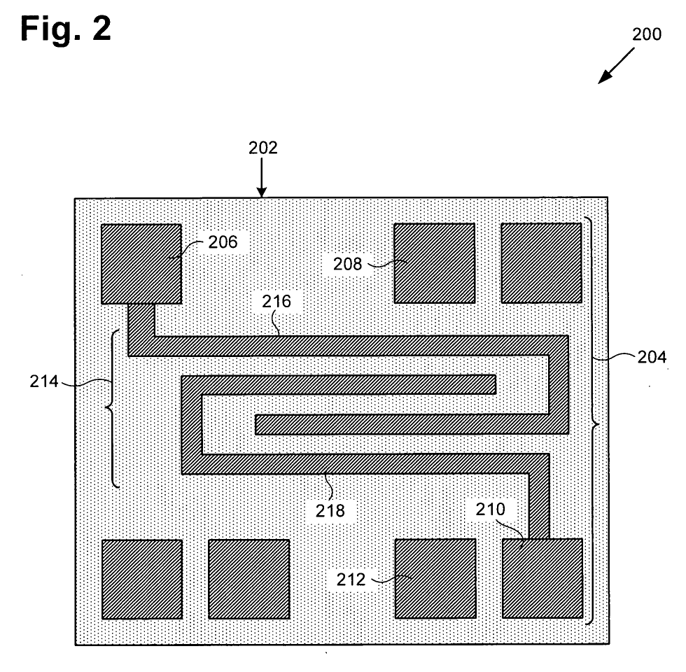

FIG. 2 shows a top view of overmolded semiconductor package 200 including an exemplary patterned conductive layer in accordance with one embodiment of the present invention. Certain details and features have been left out of FIG. 2 that are apparent to a person of ordinary skill in the art. Overmolded semiconductor package 200 includes mold compound 202 and patterned conductive layer 204, which includes conductive pads 206, 208, 210, and 212 (hereinafter “conductive pads 206 through 212”) and capacitor 214 including conductive segments 216 and 218, which form respective plates of capacitor 214. In other embodiments, patterned conductive layer 204 can include one or more inductors and/or one or more resistors.

As shown in FIG. 2, conductive pads 206 through 212 and conductive segments 216 and 218 of patterned conductive layer 204 are situated on the top surface of mold compound 202. Patterned conductive layer 204 can be substantially similar in composition and formation to patterned conductive layer 128 in FIG. 1. In one embodiment, patterned conductive layer 204 can include one or more inductors. Conductive pads 206 through 212 can be electrically coupled to one or more active devices, such as die 106 or die package 108 in FIG. 1, one or more passive components, such as surface mount component 110 in FIG. 1, and/or one or more bond pads, such as bond pads 114 or 118, which are situated over an underlying package substrate (not shown in FIG. 2), such as package substrate 104 in FIG. 1. Conductive segment 216 is connected to conductive pad 206, which forms a first terminal of capacitor 214, and conductive segment 218 is connected to conductive pad 210, which forms a second terminal of capacitor 214.

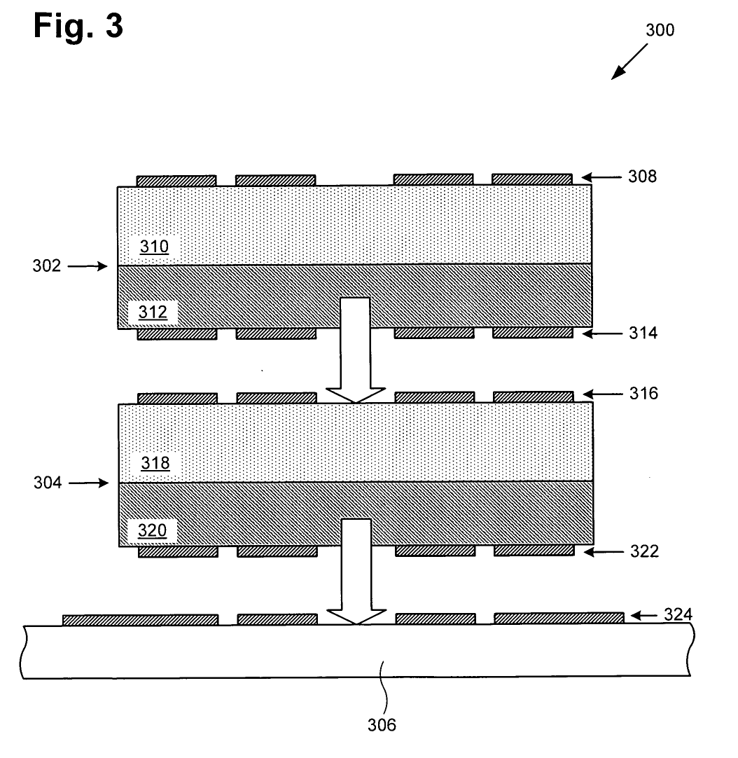

FIG. 3 shows a diagram of structure 300 including exemplary overmolded semiconductor packages situated in a stacked configuration in accordance with one embodiment of the present invention. Structure 300 includes overmolded semiconductor packages 302 and 304 (also referred to simply as “packages 302 and 304”) and circuit board 306, which can be a surface mount technology (SMT) circuit board. Overmolded semiconductor packages 302 and 304 can each be, for example, LGA packages. Overmolded semiconductor package 302 includes patterned conductive layer 308, mold compound 3 10, package substrate 312, and metal pad array 314 and overmolded semiconductor package 304 includes patterned conductive layer 316, mold compound 318, package substrate 320, and metal pad array 322. Circuit board 306 includes metal pad array 324.

As shown in FIG. 3, packages 302 and 304 are coupled together in a stacked configuration on circuit board 306, wherein metal pad array 322 on package substrate 320 of package 304 is electrically connected to metal pad array 324 on circuit board 306 and patterned conductive layer 316, which is situated on the top surface of mold compound 318 of package 304, is electrically connected to metal pad array 314 of package 302. Patterned conductive layer 308, which is situated on the top surface of mold compound 310, and patterned conductive layer 316 can be substantially similar in composition and formation to patterned conductive layer 128 in FIG. 1. Patterned conductive layers 308 and 316 can be electrically connected to active and/or passive components and/or bond pads (not shown in FIG. 3) on package substrates 312 and 320 by conductive interconnects (not shown in FIG. 3), such as conductive vias and/or metal wires, situated in respective mold compounds 310 and 318.

In a stacked conventional LGA package configuration, each conventional LGA package requires a package substrate having increase surface area to accommodate solder pads which surround the mold compound on the top surface of the package substrate. In contrast, by forming patterned conductive layers on the top surface of the mold compound in each package, an embodiment of the invention in FIG. 3 provides stacked packages having a significantly reduced footprint compared to stacked conventional LGA packages. Although only two stacked packages are shown in FIG. 3 to preserve brevity, it is manifest that more than two of the invention's overmolded semiconductor packages can be stacked on a circuit board, such as circuit board 306.

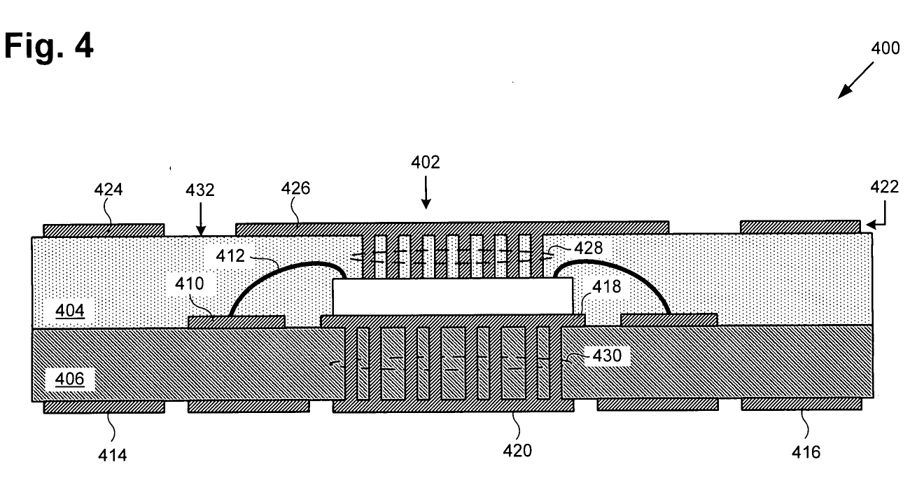

FIG. 4 shows a cross-sectional view of overmolded semiconductor package 400 including an exemplary mold compound circuit structure in accordance with one embodiment of the present invention. Certain details and features have been left out of FIG. 4 that are apparent to a person of ordinary skill in the art. Overmolded semiconductor package 400 includes mold compound circuit structure 402, mold compound 404, package substrate 406, semiconductor die 408, bond pad 410, wirebond 412, I/O pads 414 and 416, metal pad 418, and heat spreader 420. Mold compound circuit structure 402 includes patterned conductive layer 422, which includes conductive pads 424 and 426, and conductive vias 428, which are also referred to as “thermal vias” in the present application. Patterned conductive layer 422 can also include passive components, such as inductors and/or capacitors, which are not shown in FIG. 4.

As shown in FIG. 4, I/O pads 414 and 416 and heat spreader 420 are situated on the bottom surface of package substrate 406 and can be substantially similar in composition to I/O pads 124 and 126 in FIG. 1. Package substrate 406 can be substantially similar in composition to package substrate 104 in FIG. 1. Also shown in FIG. 4, conductive vias 430 are situated in package substrate and are electrically connected to heat spreader 420. Conductive vias 430 can comprise copper or other highly conductive metal or metal stack and can be formed in a manner known in the art. Further shown in FIG. 4, bond pad 410 and metal pad 418 are situated on the top surface of package substrate 406, semiconductor die is situated over metal pad 418 and electrically connected to bond pad 410 by metal wire 412. Metal pad 418 is electrically connected to conductive vias 430.

Also shown in FIG. 4, mold compound 404 is situated over the top surface of package substrate 406 and encapsulates semiconductor die 408, bond pad 410, and metal wire 412. Mold compound 404 can be substantially similar in composition and thickness to mold compound 112 in FIG. 1. Further shown in FIG. 4, conductive vias 428 are situated in mold compound 404 and overlie semiconductor die 408. Conductive vias 428 can be substantially similar in composition and formation to conductive vias 130 and 132 in FIG. 1. Also shown in FIG. 4, conductive pads 424 and 426 are situated on top surface 432 of mold compound 404 and can be substantially similar in composition and formation to conductive pads 140 through 148 in FIG. 1. To preserve brevity, only I/O pads 414 and 416, bond pad 410, metal wire 412, and conductive pads 424 and 426 are specifically discussed herein.

In overmolded semiconductor package 400, conductive vias 428 provide thermal conduits in mold compound 404 for drawing heat away from the frontside of semiconductor die 408. Conductive vias 428 are in contact with conductive pad 426, which dissipates the heat conducted by conductive vias 428 from the frontside of semiconductor die 408. Also, in overmolded semiconductor package 400, conductive vias 430 provide thermal conduits in package substrate 406 for drawing heat away from the backside of semiconductor die 408. Conductive vias 430 are connected between metal pad 418 and heat spreader 420, which dissipates the heat conducted from the backside of semiconductor die 408 by conductive vias 430. Thus, by forming conductive vias in mold compound 404 and in package substrate 406, an embodiment of the invention provides effective heat dissipation from both the frontside and backside of semiconductor die 408. In one embodiment, conductive vias 428 can provide thermal conduits to the backside of a semiconductor die that is mounted on package substrate 406 in a flip-chip configuration.

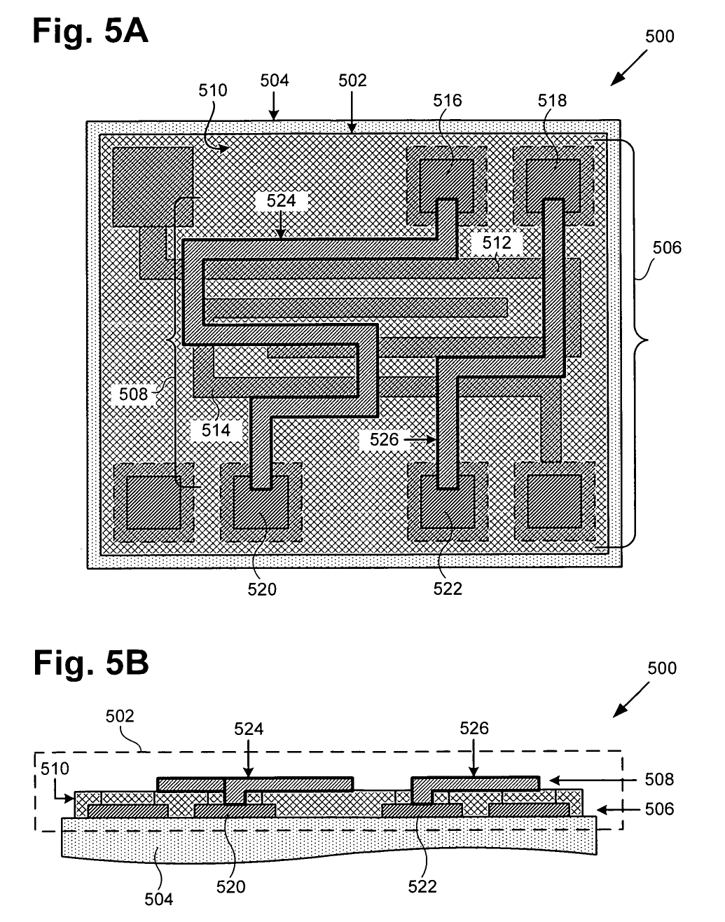

FIG. 5A shows a top view of overmolded semiconductor package 500 including an exemplary mold compound circuit structure in accordance with one embodiment of the present invention. Certain details and features have been left out of FIG. 5A that are apparent to a person of ordinary skill in the art. Overmolded semiconductor package 500 includes mold compound circuit structure 502, mold compound 504, and a package substrate (not shown in FIG. 5A), such as package substrate 104 in FIG. 1. Mold compound circuit structure 502 includes patterned conductive layers 506 and 508 and dielectric layer 510. In FIG. 5A, patterned conductive layer 506 and mold compound 504 correspond, respectively, to patterned conductive layer 204 and mold compound 202 in overmolded semiconductor package 200 in FIG. 2. Patterned conductive layer 506 includes conductive segments 512 and 514 and conductive pads 516, 518, 520, and 522. Patterned conductive layer 508 includes conductive segments 524 and 526. In other embodiments, patterned conductive layer 508 can include a patterned resistor, inductor, or capacitor network.

As shown in FIG. 5A, patterned conductive layer 506 is situated on the top surface of mold compound 504, dielectric layer 510 is situated over patterned conductive layer 506, and patterned conductive layer 508 is situated over dielectric layer 510. Patterned conductive layer 506 can be substantially similar in composition and formation to patterned conductive layer 204 in FIG. 2. Dielectric layer 510 can comprise silicon oxide or other suitable dielectric material and can be formed by depositing a layer of dielectric material over patterned conductive layer 506 by utilizing a chemical vapor deposition (CVD) process or other suitable dielectric process. The layer of dielectric material can be appropriately patterned to form openings over respective conductive pads 516, 518, 520, and 522 by utilizing, for example, a suitable etch process. Examples of such openings are indicated by dashed lines forming a square around each respective conductive pad 516, 518, 520, and 522 in FIG. 5A.

Patterned conductive layer 508 can be formed by depositing a layer of conductive material, such as copper, gold, or other suitable metal or metal stack, over dielectric layer 510 and patterning the layer of conductive material so as to form conductive segments 524 and 526. Conductive segment 524 can be an inductor and is electrically connected between conductive pads 516 and 520 and conductive segment 526 can be a resistor and is electrically connected between conductive pads 518 and 522.

FIG. 5B shows a side view of overmolded semiconductor package 500 in FIG. 5A. In particular, mold compound circuit structure 502, mold compound 504, patterned conductive layers 506 and 508, dielectric layer 510, conductive pads 520 and 522, and conductive segments 524 and 526 correspond to the same elements in FIG. 5A and FIG. 5B. As shown in FIG. 5B, conductive segment 524 is in electrical contact with conductive pad 520 and conductive segment 526 is in electrical contact with conductive pad 522.

In the embodiment in FIGS. 5A and 5B, the invention provides a mold compound circuit structure situated on a top surface of a mold compound, where the mold compound circuit structure includes two patterned conductive layers and a dielectric layer interposed between the patterned conductive layers. In other embodiments, the invention's mold compound circuit structure can include repeated layers of patterned dielectric, conductive, resistive, magnetic, absorbing, and other types of material situated on the top surface of mold compound in an overmolded semiconductor package.

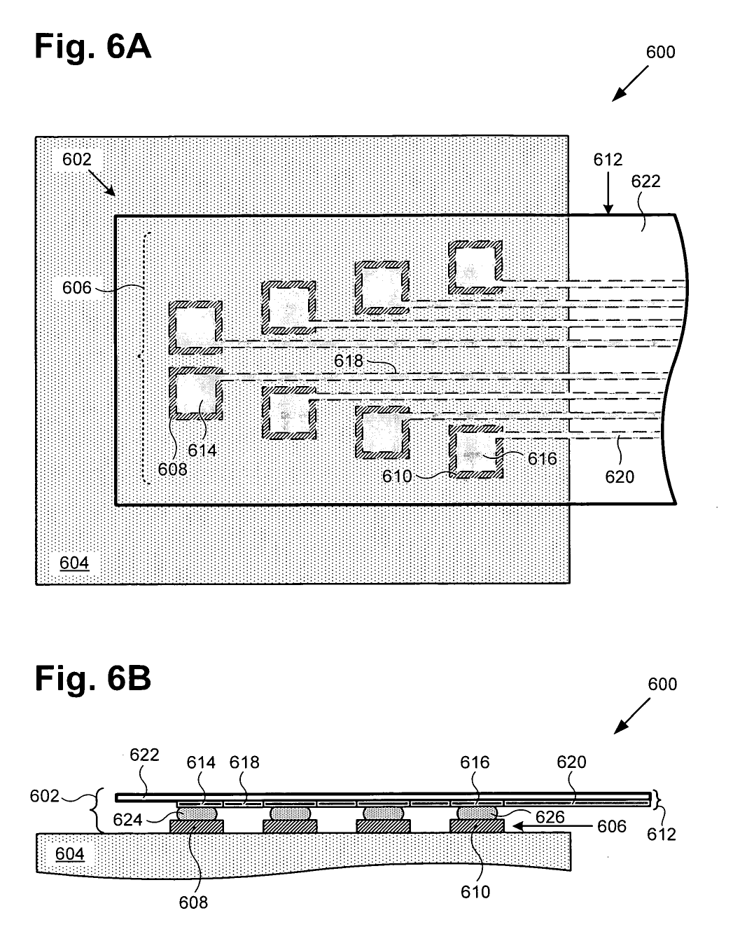

FIG. 6A shows a top view of overmolded semiconductor package 600 including an exemplary mold compound circuit structure in accordance with one embodiment of the present invention. Certain details and features have been left out of FIG. 6A that are apparent to a person of ordinary skill in the art. Overmolded semiconductor package 600 includes mold compound circuit structure 602, mold compound 604, and a package substrate (not shown in FIG. 6A), such as package substrate 104 in FIG. 1. Mold compound circuit structure 602 includes patterned conductive layer 606, which includes conductive pads 608 and 610, and flexible connector 612, which includes conductive pads 614 and 616, conductive segments 618 and 620, and flexible substrate 622. Only conductive pads 608, 610, 614, and 616 and conductive segments 618 and 620 are specifically discussed herein to preserve brevity.

As shown in FIG. 6A, conductive pads 608 and 610 are situated on the top surface of mold compound 604. Conductive pads 608 and 610 can be substantially similar in composition and formation to conductive pads 140 through 148 in FIG. 1. Mold compound 604 can be substantially similar in composition and formation to mold compound 112 in FIG. 1. Also shown in FIG. 6A, conductive pads 614 and 616 and conductive segments 618 and 620 are situated on the bottom surface of flexible substrate 622 and can comprise a metal, such as copper or gold, or other type of conductive material. Flexible substrate 622 can comprise a suitable flexible dielectric material as is known in the art. Flexible connector 612 can be formed by forming conductive pads 614 and 616 and conductive segments 618 and 620 on the bottom surface of flexible substrate 622 by utilizing suitable deposition and patterning processes.

FIG. 6B shows a side view of overmolded semiconductor package 600 in FIG. 6A. In particular, mold compound circuit structure 602, mold compound 604, patterned conductive layer 606, conductive pads 608, 610, 614, and 616, flexible connector 612, conductive segments 618 and 620, and flexible substrate 622 correspond to the same elements in FIG. 6A and FIG. 6B. As shown in FIG. 6B, conductive pads 608 and 610 of patterned conductive layer 606 are situated on the top surface of mold compound 604 and are electrically connected to conductive pads 614 and 616 of flexible connector 612 by respective conductive material segments 624 and 626. Conductive material segments 624 and 626 can comprise solder, conductive epoxy, or other suitable conductive material.

In the embodiment in FIGS. 6A and 6B, the invention provides a mold compound circuit structure situated on a top surface of a mold compound, where the mold compound circuit structure includes a patterned conductive layer electrically connected to a flexible connector. In other embodiments, the invention's mold compound circuit structure can include a patterned conductive layer situated on a mold compound and electrically connected to other types of flexible connectors as well as non-flexible connectors and cables.

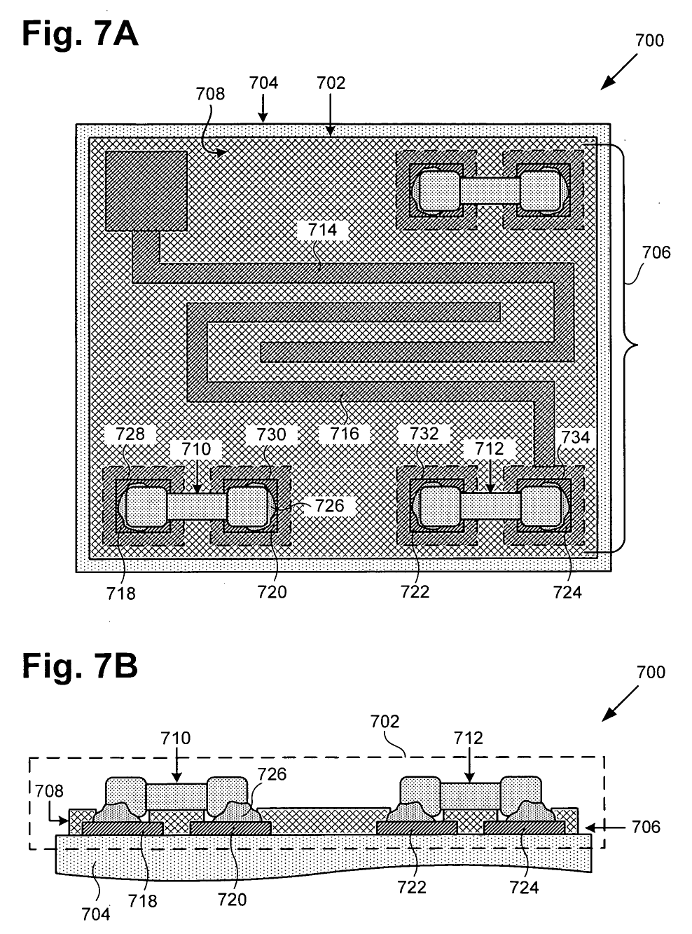

FIG. 7A shows a top view of overmolded semiconductor package 700 including an exemplary mold compound circuit structure in accordance with one embodiment of the present invention. Certain details and features have been left out of FIG. 7A that are apparent to a person of ordinary skill in the art. Overmolded semiconductor package 700 includes mold compound circuit structure 702, mold compound 704, and a package substrate (not shown in FIG. 7A), such as package substrate 104 in FIG. 1. Mold compound circuit structure 702 includes patterned conductive layer 706, dielectric layer 708, and surface mount components 710 and 712. In FIG. 5A, patterned conductive layer 706 and mold compound 704 correspond, respectively, to patterned conductive layer 204 and mold compound 202 in overmolded semiconductor package 200 in FIG. 2. Patterned conductive layer 706 includes conductive segments 714 and 716 and conductive pads 718, 720, 722, and 724 (hereinafter “conductive pads 718 through 724”). Only surface mount components 710 and 712 and conductive pads 718 through 724 are specifically discussed herein to preserve brevity.

As shown in FIG. 7A, patterned conductive layer 706 is situated on the top surface of mold compound 704 and dielectric layer 708 is situated over patterned conductive layer 706. Patterned conductive layer 706 can be substantially similar in composition and formation to patterned conductive layer 204 in FIG. 2. Dielectric layer 708 can comprise silicon oxide or other suitable dielectric material and can be formed by depositing a layer of dielectric material over patterned conductive layer 706 by utilizing a CVD process or other suitable dielectric process. The layer of dielectric material can be appropriately patterned to form openings 728, 730, 732, and 734 over respective conductive pads 718, 720, 722, and 724 by utilizing, for example, a suitable etch process.

Also shown in FIG. 7A, surface mount components 710 and 712 are situated over dielectric layer 708 and can each be a capacitor. In other embodiments, surface mount components 710 and 712 can each be a resistor or an inductor. Surface mount component 710 is electrically connected to conductive pads 718 by solder 726 and surface mount component 712 is electrically connected to conductive pads 722 and 724 by solder 726. In other embodiments, surface mount components 710 and 712 can be connected to conductive pads in patterned conductive layer 706 by a conductive epoxy or other suitable conductive adhesive material.

FIG. 7B shows a side view of overmolded semiconductor package 700 in FIG. 7A. In particular, mold compound circuit structure 702, mold compound 704, patterned conductive layer 706, dielectric layer 708, surface mount components 710 and 712, conductive pads 718 through 724, and solder 726 correspond to the same elements in FIG. 7A and FIG. 7B. As shown in FIG. 7B, surface mount component 710 is electrically connected between conductive pads 718 and 720 and surface mount component 712 is electrically connected between conductive pads 722 and 724.

In the embodiment in FIGS. 7A and 7B, the invention provides a mold compound circuit structure situated on a top surface of a mold compound, where the mold compound circuit structure includes a patterned conductive layer, a dielectric layer, and a number of surface mount components. In the embodiment in FIGS. 7A and 7B, each surface mount component is electrically connected to underlying conductive pads in the patterned conductive layer through corresponding openings in the dielectric layer.

In other embodiments, the invention's overmolded semiconductor package can include a mold component circuit structure that includes multiple flex or ceramic antennas for communication using Wi-fi, cellular, Worldwide Interoperability for Microwave Access (WiMAX), or Long Term Evolution (LTE) communication standards. In other embodiments, the invention's overmolded semiconductor package can include a mold component circuit structure including a tunable inductor or tunable capacitor array formed in patterned conductive layer, where the inductor can be tuned by trimming its length and the capacitor array can be tuned by adding or eliminating capacitance. In one embodiment, the invention's overmolded semiconductor package can include a mold component circuit structure that provides thermal cooling for a power amplifier die by forming metal wires in the mold compound overlying heat generating areas of the die and utilizing the metal wires as thermal conduits to pull heat to the top surface of the mold compound. In such embodiment, a conductive pad can be formed on the top surface of the mold compound and thermally connected to a heat frame by thermal grease.

Thus, as discussed above, the invention provides a mold compound circuit structure in an overmolded semiconductor package, where the mold compound circuit structure can include one or more patterned conductive layers for advantageously adding passive components and circuitry and electrical connectivity to the top surface of the mold compound in the package. The invention's mold compound circuit structure can also include thermal vias for advantageously conducting heat away from a semiconductor die in the overmolded semiconductor package. The invention's mold compound circuit structure can further include conductive interconnects, such as conductive vias and metal wires, situated in the mold compound, where the conductive interconnects can provide electrical connections between a patterned conductive layer situated on the top surface of the mold compound and passive components, bond pads, and/or semiconductor dies residing on the package substrate of the overmolded semiconductor package.

From the above description of the invention it is manifest that various techniques can be used for implementing the concepts of the present invention without departing from its scope. Moreover, while the invention has been described with specific reference to certain embodiments, a person of ordinary skill in the art would appreciate that changes can be made in form and detail without departing from the spirit and the scope of the invention. Thus, the described embodiments are to be considered in all respects as illustrative and not restrictive. It should also be understood that the invention is not limited to the particular embodiments described herein but is capable of many rearrangements, modifications, and substitutions without departing from the scope of the invention.

Thus, a mold compound circuit structure for enhanced electrical and thermal performance has been described.

1. An overmolded semiconductor package comprising:
at least one semiconductor die situated over a package substrate;
a mold compound overlying said at least one semiconductor die and said package substrate and having a top surface;
a first patterned conductive layer situated on said top surface of said mold compound.

2. The overmolded semiconductor package of claim 1 further comprising at least one conductive interconnect situated in said mold compound, wherein said at least one conductive interconnect is electrically connected to said first patterned conductive layer.

3. The overmolded semiconductor package of claim 2, wherein said at least one conductive interconnect provides an electrical connection between said first patterned conductive layer and said at least one semiconductor die.

4. The overmolded semiconductor package of claim 2 further comprising at least one bond pad situated on said package substrate, wherein said at least one conductive interconnect provides an electrical connection between said first patterned conductive layer and said at least one bond pad.

5. The overmolded semiconductor package of claim 1, wherein said first patterned conductive layer comprises at least one passive component.

6. The overmolded semiconductor package of claim 1 further comprising at least one thermal via situated in said mold compound and situated over said at least one semiconductor die, wherein said at least one thermal via is in contact with said first patterned conductive layer.

7. The overmolded semiconductor package of claim 1 further comprising a second patterned conductive layer situated over said first patterned conductive layer.

8. The overmolded semiconductor package of claim 7, wherein said second patterned conductive layer comprises at least one passive component.

9. The overmolded semiconductor package of claim 1 further comprising at least one surface mount component situated over and electrically connected to said first patterned conductive layer.

10. The overmolded semiconductor package of claim 1 further comprising a flexible connector situated over and electrically connected to said first patterned conductive layer.

11. A method of forming an overmolded semiconductor package, said method comprising:
forming a mold compound over a package substrate and at least one semiconductor die situated thereon, said mold compound encapsulating said at least one semiconductor die;
forming a first patterned conductive layer on said mold compound.

12. The method of claim 11 further comprising exposing a metal wire situated in said mold compound prior to forming said first patterned conductive layer.

13. The method of claim 12, wherein said metal wire provides an electrical connection between said at least one semiconductor die and said first patterned conductive layer.

14. The method of claim 12, wherein at least one bond pad is situated on said package substrate, wherein said metal wire provides an electrical connection between said at least one bond pad and said first patterned conductive layer.

15. The method of claim 11 further comprising forming at least one conductive via in said mold compound prior to forming said first patterned conductive layer.

16. The method of claim 15, wherein at least one passive component is situated on said package substrate, wherein said at least one conductive via provides an electrical connection between said at least one passive component and said first patterned conductive layer.

17. The method of claim 11, wherein said first patterned conductive layer comprises at least one passive component.

18. The method of claim 11 further comprising forming a second patterned conductive layer over said first patterned conductive layer.

19. The method of claim 18, wherein said second patterned conductive layer comprises at least one passive component.

20. The method of claim 11 further comprising mounting at least surface mount component on said first patterned conductive layer.
